(19) United States
(12) Patent Application Publication
(10) Pub. No.: US 2026/0261090 A1
(43) Pub. Date: Sep. 3, 2026

(54) METHOD TO STABILIZE A WAVELENGTH OF A TUNABLE LASER DEVICE, TUNABLE LASER DEVICE, AND POSITION MEASUREMENT SYSTEM PROVIDED WITH THE TUNABLE LASER DEVICE

(71) Applicant: ASML Netherlands B.V., Veldhoven (NL)

(72) Inventors: Maarten Jozef JANSEN, Hoogeloon (NL); Eduard Martinus KLARENBEEK, Sorendonk (NO)

(73) Assignee: ASML Netherlands B.V., Veldhoven (NL)

(21) Appl. No.: 18/876,006

(22) PCT Filed: Jul. 13, 2024
(86) PCT No.: PCT/EP2023/069432

§ 371 Date: Dec. 17, 2024

(30) Foreign Application Priority Data
Aug. 18, 2022 (EP) 22190984.9
Sep. 8, 2022 (EP) 22194604.9

(51) Int. Cl. H01S 3/13; G01B 11/14; G03F 7/00; G03F 9/00

(52) U.S. Cl. CPC H01S 3/1305; G01B 11/14; G03F 7/70516; G03F 7/7085; G03F 9/7088

(57) ABSTRACT

A wavelength of a tunable laser device is stabilized by providing a laser beam from a tunable laser source to an interferometer having a stable reference axis and to a gas absorption cell, scanning the laser beam between first and second wavelengths to determine absorption cell transmission spectrum as a function of wavelength difference; using the interferometer to determine phase change as a function of the wavelength difference; determining a transmission spectrum as a function of the phase change using the gas absorption cell transmission spectrum and phase change as a function of wavelength difference; correlating the determined transmission spectrum as a function of phase change to a pre-calibrated transmission spectrum of the tunable laser device to provide absolute laser wavelength as a function of the phase change; defining phase setpoint corresponding to wavelength setpoint; using the phase setpoint to tune the tunable laser device to the wavelength setpoint.

### CROSS-REFERENCE TO RELATED APPLICATION

The application claims priority of EP Application Serial No. 22190984.9 which was filed on 18 Aug. 2022 and EP Application Serial No. 22194604.9 which was filed on 8 Sep. 2022, and which are incorporated herein in their entirety by reference.

### FIELD

The technology relates to controlling the wavelength of a laser output of a tunable laser device. The tunable laser device may be used, for instance, to monitor displacement of equipment in a lithographic apparatus. For example, the tunable laser device and the disclosed methods of controlling the wavelength thereof may be applied in projection systems for optical lithography systems.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Tunable lasers have been widely used over the past several decades to measure the wavelength response of optical systems. Early applications were primarily in spectroscopy. Since the advent of wavelength division multiplexing in optical telecommunications, tunable laser applications have increased in the field of telecommunications components measurement.

In semiconductor manufacturing processes, tunable lasers are often used for precision measurement of the position of various elements of the lithographic apparatus. Said elements may be moveable, such as the wafer stage. Herein, the laser measurement system may provide information relating to the accurate position of the respective element with respect to other elements in the optical system, such as a reference, a mask or the source of radiation. The elements may also be intended to remain stationary, such as the radiation source, the mask, lenses and/or mirrors. Herein, the laser measurement system can be used to monitor unwanted deviation from a predetermined location, for instance due to thermal drift.

The term “tunable laser” refers to wavelength tunable lasers. A tunable laser measurement system typically includes a laser and a measurement device and/or method for determining the wavelength of the laser. A tunable laser control system includes a mechanism for calculating an error signal corresponding to the difference between current wavelength and a desired setpoint. The error signal is used to drive the laser actuator(s).

A key component for a tunable laser measurement or controls system is the wavelength measurement itself. Various types of instruments and methods that can be used for this include the following, among others: Fizeau interferometer, grating spectrum analyser, Fourier spectrometer, and etalon/wavelength reference combination. Additional methods include mapping wavelength response to actuator angle or position.

US20200182702A1 discloses a tunable laser system including a tunable laser to be scanned over a range of frequencies and an interferometer having a plurality of interferometer outputs. At least two interferometer outputs of the plurality of interferometer outputs have a phase difference. A wavelength reference has a spectral feature within the range of frequencies, and the spectral feature does not change in an expected operating environment of the tunable laser. Processing circuitry uses the spectral feature and the plurality of interferometer outputs to produce an absolute measurement of a wavelength of the tunable laser and controls the tunable laser based on a comparison of the absolute measurement of the wavelength of the tunable laser with a setpoint wavelength.

As described in US20200182702A1, it may be desirable that the measured wavelength signal exhibits one or more of the following characteristics: 1. directional: the wavelength measurement contains information about the direction of the laser tuning, 2. continuous: the measurement is available continuously, both temporally, and across the tuning range of the laser, 3. high accuracy: for applications such as spectroscopy and optical sensing, accuracy down to sub-pm levels is favourable and in some cases crucial, 4. high precision: accuracy is rarely meaningful unless precision is, at a maximum, equal to the accuracy of the control; many applications benefit from precision orders of magnitude better than accuracy, 5. absolute information: without absolute information, it is possible only to obtain a relative wavelength measurement; an unknown wavelength offset will exist between the wavelength measurement and actual wavelength, 6. no or negligible drift: many applications are sensitive to short- or long-term drift, 7. low latency: this requirement is particularly applicable to utilization of the wavelength measurement in a controls system; latency refers to the time taken between light exiting the laser and applying appropriate corrective signals to laser actuators. Time taken in calculation of the error signal contributes to the total latency, which latency is inversely proportional to feedback loop bandwidth; higher frequency control is available with decreasing latency.

Although the system of US20200182702A1 lives up to all these characteristics, the system uses a feedback loop which introduces delay and in practice results in an iterative process of adjusting the actual laser wavelength to a setpoint based on error correction.

US20020043616A1 discloses a system and method for calibrating a tunable laser such as a widely tunable laser (WTL). This is done by routing the laser's output through a gas cell and an etalon and varying tuning parameters of the laser and comparing the spectrum of the two signals. This can be used to determine an absolute transmission wavelength for the WTL as a function of the tuning parameters (such as temperature). The described solution can be used to calibrate an etalon for different temperatures, as an example.

A significant disadvantage of the system of US20020043616A1 relates to the tuning. The system compares and locks to peaks in the spectrum. As a result, the calibration of the laser is practically limited to the specific frequencies or wavelengths of the peaks.

In addition, known methods typically require wavelength modulation or frequency sideband generation using electro-optical modulators (EOMs). When locking to a gas absorption cell, it is not possible to lock to a frequency that is between spectral lines. Sideband locking does give some flexibility in between spectral lines, but it is unviable to freely choose any position in between absorption lines because of the large frequency tuning range of the EOM that would be required.

Existing methods stabilize laser frequency in the source instead of the laser wavelength in the interferometer itself. Such methods require additional complex wavelength stabilization via for instance software-based compensation that can induce errors, specifically cyclic errors, and also require knowledge about optical path difference (OPD) ratios between interferometer axes. A wavelength tracker is traditionally intended to measure laser frequency and refractive index noise and provides data for use in software-based compensation.

The present disclosure aims to provide an improved method and system allowing laser wavelength control, overcoming at least one or more of the disadvantages of the prior art.

### SUMMARY

The present disclosure provides a method to stabilize a wavelength of a tunable laser device, comprising the steps of:
simultaneously providing a laser beam from a tunable laser source to a first interferometer having a mechanically stable reference axis and to a gas absorption cell;
scanning a wavelength range with the laser beam from a first wavelength to a second wavelength;
determining a transmission spectrum of the gas absorption cell as a function of the wavelength difference with respect to the first wavelength;
using the first interferometer to determine a phase change as a function of the wavelength difference with respect to the first wavelength;
determining a transmission spectrum as a function of the phase change using the transmission spectrum of the gas absorption cell and the phase change as a function of the wavelength difference;
correlating the determined transmission spectrum as a function of phase change to a pre-calibrated transmission spectrum of the tunable laser device to provide an absolute laser wavelength as a function of the phase change;
defining a phase setpoint corresponding to a wavelength setpoint; and
using the phase setpoint to tune the tunable laser device to the wavelength setpoint.

In an embodiment, the method includes the step of: using the laser beam set at the setpoint wavelength to measure displacement of a device in a lithographic apparatus. The device may comprise a wafer table, a wafer, a mask, a mask table, or any other piece of equipment in the optical stage of the lithographic apparatus.

The step of using the laser beam to measure displacement may include providing the laser beam to a second interferometer.

The steps of correlating the determined transmission spectrum as a function of phase change to the pre-calibrated transmission spectrum of the tunable laser device may comprise: fitting the determined transmission spectrum to the pre-calibrated transmission spectrum using a fitting algorithm.

The step of using the phase setpoint to tune the tunable laser device to the setpoint wavelength may comprise continuously using the first interferometer to determine a phase change with respect to the phase setpoint.

According to another aspect, the disclosure provides a tunable laser device, comprising:
a tunable laser source for providing a laser beam;
a first interferometer having a mechanically stable reference axis adapted to receive the laser beam,
a gas absorption cell adapted to receive the laser beam simultaneously with the interferometer,
a processor adapted for:
scanning a wavelength range with the laser beam from a first wavelength to a second wavelength,
determining a transmission spectrum of the gas absorption cell as a function of time;
using the first interferometer to determine a phase change as a function of time;
determining a transmission spectrum as a function of the phase change using the transmission spectrum of the gas absorption cell and the phase change as a function of time;
correlating the determined transmission spectrum as a function of phase change to a pre-calibrated transmission spectrum of the tunable laser device to provide an absolute laser wavelength as a function of the phase change;
defining a phase setpoint corresponding to a wavelength setpoint; and
using the phase setpoint to tune the tunable laser device to the wavelength setpoint.

Herein, determining a transmission spectrum of the gas absorption cell as a function of time may include correlating time to the wavelength difference with respect to the first wavelength.

Using the first interferometer to determine a phase change as a function of time may include correlating time to the wavelength difference with respect to the first wavelength.

The laser device may be adapted to use the laser beam set at the wavelength setpoint to measure displacement of a device in a lithographic apparatus.

The device may comprise a second interferometer adapted to receive the laser beam to measure displacement.

The device in the lithographic apparatus may comprise a wafer table, a wafer, a mask, a mask table, or any other piece of equipment in the optical stage of the lithographic apparatus.

The processor may be adapted to correlate the determined transmission spectrum to the pre-calibrated transmission by fitting the determined transmission spectrum to the pre-calibrated transmission spectrum using a fitting algorithm.

The tunable laser device may be adapted to have an operating mode, wherein the first interferometer is adapted to continuously determine a phase change with respect to the phase setpoint.

According to yet another aspect, the disclosure provides a position measurement system, comprising a tunable laser device adapted to implement the method of claim 1.

According to another aspect, the disclosure provides a lithographic apparatus, comprising at least one position measurement system as referenced above.

The method and device of the disclosure use a phase measuring interferometer. Using the phase to adjust the wavelength of the laser obviates the limitations of calibrating against the transmission lines, for instance of an etalon. The phase measurement allows continuous measurement and adjustment (instead of discrete steps). This renders the wavelength control more accurate. Also, the phase measurement can be continuous (in time), so that any deviation from a set wavelength can immediately be corrected without a need to sweep or other iterative steps. The method of the disclosure obviates active control of the length of the optical cavity to perform a calibration.

The cavity of the wavelength tracker part of the interferometer is, preferably, as stable and as fixed as possible. The method obviates to detect transmission lines of the optical cavity.

With the method and apparatus of the disclosure, laser wavelength stabilization can be achieved by calibrating the phase of an interferometer wavelength tracker against the spectral absorption spectrum of a molecular absorption cell. It is proposed to lock to the phase of the wavelength tracker (which has a mechanically stable reference axis) to effectively stabilize the laser wavelength, instead of the laser frequency. The control loop that keeps a constant phase in the wavelength tracker signal prevents manifestation of cyclic errors. No wavelength modulation is required, and locking is not limited to specific wavelength values. Thus, wavelength compensation is inherent and no longer has to be applied in software, and no OPD ratio information is required.

### BRIEF DESCRIPTION OF THE DRAWINGS

Embodiments of the invention will now be described, by way of example only, with reference to the accompanying schematic drawings, in which:

FIG. 1 depicts a schematic overview of an exemplary lithographic apparatus;

FIG. 2 depicts a schematic overview of an embodiment of a tunable laser device;

FIG. 3A depicts steps in an embodiment of a method of the disclosure;

FIG. 3B depicts an exemplary embodiment of the method of the disclosure, combining various inputs to arrive at a diagram linking wavelength tracker phase to absolute wavelength;

FIG. 3C depicts exemplary diagrams, indicating steps in a method of the disclosure;

FIG. 4 depicts an exemplary diagram linking wavelength tracker phase to absolute wavelength;

FIG. 5 depicts a schematic overview of the tunable laser device, in an operating mode of the laser device in accordance with a method of the disclosure; and

FIG. 6 depicts a schematic overview of another embodiment of a tunable laser device.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

“Refractive Index” (Index of Refraction) is a value calculated from the ratio of the speed of light in a vacuum to that in a second medium of greater density. The refractive index variable may be symbolized by the letter n or n′ in descriptive text and mathematical equations.

An “interferometer” or a “laser interferometer” can measure distance by measuring the phase difference between two light beams, one sent to a first reflector or first surface at a fixed reference distance, and one sent to a second reflector or surface at another distance. When the two reflected signals are recombined in the interferometer, the resulting phase is related to the distance of the second surface from the interferometer. If the distance of the second surface changes, so does the phase of the combined signal. The utility of these methods are that the measurement can be made over long distances while maintaining accuracy.

In a heterodyne interferometer, the measurement beam and reference beam that interfere at a detector are generally originating from the same laser source. The source may have been given a frequency offset to allow for heterodyne phase detection. The two (split) frequencies may however also be generated by two different, frequency-locked or phase-locked lasers.

A “wavelength tracker” is a specific version of an interferometer set up to measure a phase difference between two reflected light beams, one beam reflecting on a first fixed reflector providing a first reference axis and a second beam reflecting on a second fixed reflector providing a second reference axis having a different length than the first axis. As the two reflective surfaces are fixed, the measured phase difference will change only if the wavelength of the light beam changes. Thus, a wavelength tracker allows to monitor deviations of the wavelength from a setpoint.

For a general description of interferometers and details thereof, reference is made to, for instance, “A tutorial on laser interferometry for precision measurements” (Conference paper; Proceedings of the American Control Conference; June 2013; DOI: 10.1109/ACC.2013.6580402; Daniel Abramovitch et al.).

A “beam splitter” (also spelled beamsplitter) is an optical device that splits a beam of light in two. It is a part of many optical systems. In a first version, a beam splitter may be a cube, made from two triangular glass prisms which are glued together at their base using, for instance, polyester, epoxy, or urethane-based adhesives. The thickness of the adhesive resin layer is adjusted such that (for a certain wavelength) half of the light incident through one “port” (i.e., face of the cube) is reflected and the other half is transmitted due to FTIR (Frustrated Total Internal Reflection). Polarizing beam splitters, such as a Wollaston prism, use birefringent materials to split light into two beams of orthogonal polarization states. A second option is the use of a semi-transparent mirror. This is composed of an optical substrate, which is often a sheet of glass or plastic, with a partially transparent thin coating of metal. The thin coating can be aluminium or silver deposited using a physical vapor deposition method. The thickness of the coating is controlled so that part (typically half) of the light, which is incident at a 45-degree angle and not absorbed by the coating or substrate material, is transmitted and the remainder is reflected. A third version of the beam splitter is a dichroic mirrored prism assembly which uses dichroic optical coatings to divide an incoming light beam into a number of spectrally distinct output beams.

A “gas reference cell” is a cell filled with some gas, normally used in laser absorption spectroscopy. The absorption coefficient of light in the gas, or some other effect resulting from the interaction of the gas with light, such as frequency-dependent phase changes, allows comparison with a reference beam. Typically, small changes to the light beam caused by the passage through the gas are measured as a function of the optical frequency of the laser beam, and the results are presented in the form of a spectrum, for example, an absorption spectrum. The obtained peaks in such a spectrum can be used to identify certain chemical species and to measure their concentration. For such measurements, one often uses wavelength-tunable single-frequency lasers. Once the spectrum and the chemical composition in the cell is known, the gas cell also allows the opposite process of using the absorption spectrum to identify the frequency or wavelength of the laser light.

A gas reference cell is typically provided with appropriate optical windows (with high transmissivity over the whole relevant spectral region) for the light to enter and leave the cell. Reference gas cells are commercially available with many different gases, including both atomic and (often diatomic) molecular gases. Typical examples are iodine (I₂), hydrogen (H₂), helium, carbon monoxide (CO) and acetylene (C₂H₂). A wide range of standard spectral lines can thus be used. In some cases, alkali metals such as sodium (Na), potassium (K), rubidium (Rb) or cesium (Cs) are used, which develop a sufficiently high vapor pressure at least when electrically heated to some appropriate temperature. Such cells may be called vapor cells. A sealed gas cell should be reliably leak-free. Therefore, helium leak testing is often applied.

An “absorption cell” or “molecular absorption cell” is a device comprising a gas reference cell. The absorption cell can compare the difference between the intensity of two portions of the same beam, one portion sent to the gas reference cell and to a first sensor for receiving the light once it has passed through the reference cell at least once, and a second portion sent unobstructed to a second sensor used as a reference.

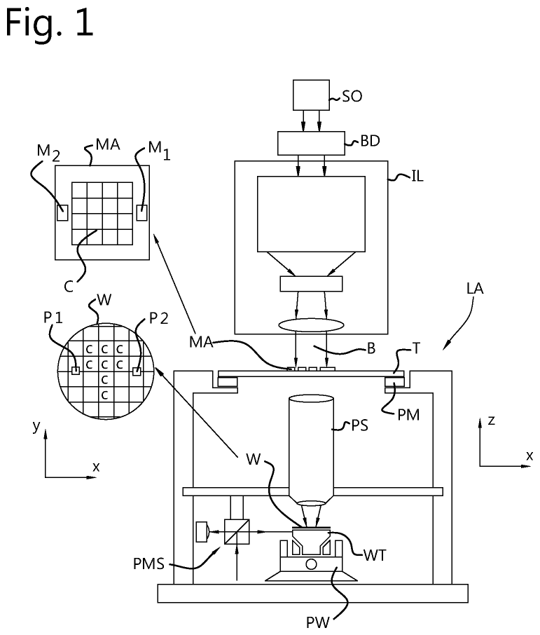

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

In vacuum, wavelength and frequency are related according to:

$$f = \frac{c}{λ}$$

wherein λ is wavelength, f is frequency, and c is the speed of light. Please note however that the wavelength becomes shorter if the wave of light moves from a first medium having a first density to a second, denser medium. The frequency of the light however does not change when the wave moves from one medium to another. The speed of the wave v is related to both the frequency f and the wavelength λ:

$$v = λ f$$

Combining the above expression for velocity with the definition of index of refraction, the relationship between the wavelength λₒ=c/f in vacuum and the wavelength λ1=v₁/f in a first medium other than vacuum is:

$$\frac{λ 0}{λ 1} = \frac{c / f}{v 1 / f} = \frac{fc}{fv 1} = \frac{c}{v 1} = n 1$$

wherein n₁ is the refractive index of the first medium.

Although the laser light may travel through a low pressure environment, a ‘vacuum’ inside a machine, such as a lithographic apparatus, is typically still denser than a theoretical vacuum. A consequence is that when setting the tunable laser to a selected setpoint, to improve accuracy it is generally preferred to determine the wavelength of the laser light while travelling through the medium, instead of tuning the frequency of the laser light in the laser itself.

In an embodiment, the method of the disclosure applies wavelength stabilization instead of laser frequency stabilization. Herein, we assume that the refractive index of the medium is identical for the mechanically ultra-stable wavelength tracker and for an interferometer axis in the measurement system.

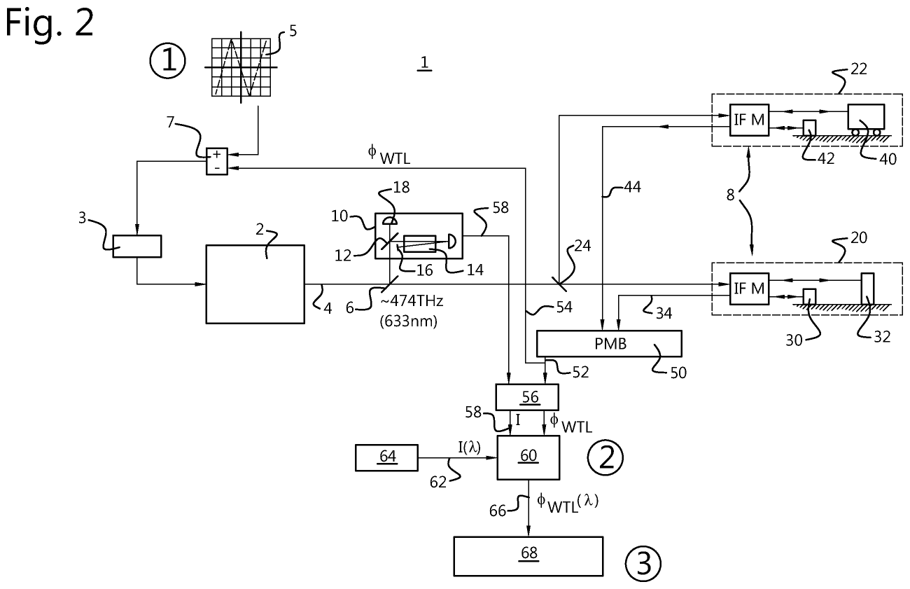

Generally referring to FIG. 2, a tunable laser device 1 according to the present disclosure comprises a tunable laser source 2 for providing a laser beam 4. The laser source is tunable meaning that the laser beam 4 can be adjusted or tuned between, at least, a first wavelength and a second wavelength. Herein, the second wavelength may exceed the first wavelength.

The laser 2 can be connected to a controller 3 to control or tune the wavelength or frequency of the laser beam 4. The controller in turn can be connected to a setpoint trajectory generator 5. The setpoint generator 5 can be set to provide a sweep to the controller 3, in effect sweeping the laser wavelength from the first wavelength to the second wavelength, and/or vice versa. The output of the setpoint trajectory generator can be provided to the controller via an adder or addition device 7. The addition device enables to add or subtract a feedback signal or feedback loop signal to the setpoint set by the generator 5. The feedback signal will be described below.

The wavelength modulation may be done by open loop control of the laser (typically by changing the temperature of the laser cavity) or in closed loop control. In closed loop control the wavelength of the laser may be adjusted by controlling, for instance, the temperature of the laser cavity to a desired setpoint trajectory (not depicted in FIG. 2) or by controlling the phase of the wavelength tracker to a desired setpoint trajectory (as depicted in FIG. 2). The setpoint generator may also be connected directly to the tuning element of the laser (typically a TEC controller) either in open loop or in closed loop. The direct connection may include a thermistor that measures the laser cavity temperature. The main purpose is that the wavelength of the laser will be tuned, multiple options are conceivable within the scope of the disclosure. FIG. 2 depicts a wavelength control loop based on the measured WLT phase. In a practical embodiment, the tuning may be done with a closed loop or open loop setpoint of the temperature of the laser cavity.

A practical embodiment of a tunable laser source is provided in, for instance, Research Disclosure database number 689021, “High Power Metrology Lasers in Interferometry”, published in the September 2021 paper journal and published digitally on 5 Aug. 2021.

The laser beam is directed to a first beam splitter 6. The first beam splitter directs one part of the beam 4 to an interferometer device 8 and another part to an absorption cell 10.

The absorption cell 10 comprises a second beam splitter 12. The second beam splitter 12 directs one portion of the light incident on the absorption cell 10 to a gas reference cell 14 having a first sensor 16. Another portion is directed to a second sensor 18.

The interferometer device 8 may comprise a first interferometer 20. The first interferometer 20 may be a wavelength tracker. The interferometer device 8 may also comprise a second interferometer 22. The second interferometer can be a distance measurement device. A third beam splitter 24 can be provided to direct one part of the light incident on the interferometer device 8 to the first interferometer 20, and a second part of the light to the second interferometer 22.

The first interferometer 20 is a wavelength tracker. The first interferometer comprises a first reflector 30 at a first distance and a second reflector at a second distance exceeding the first distance. Both the first reflector 30 and the second reflector 32 have a fixed position. The respective first and second distance are therefore constant and provide two respective fixed reference axes. Both the first reference axis and the second reference axis are preferably as stable as possible. Stable herein means that the length of both axes remains virtually constant, at least within a predetermined set of operating conditions.

In a practical embodiment, the second distance may exceed the first distance in the order of 0.5 to 10 m, for instance about 1 m. In a practical embodiment, the optical pathlength difference may be about 6 to 12 meters, for instance about 8 to 10 meters. This may be achieved in a compact housing by adopting a folded beam interferometer having multiple passes in a measurement cavity.

The second interferometer 22 may be for distance measurement or position measurement of a piece of equipment 40. Herein, the second interferometer includes a third reflector 42 located at a fixed position to provide a third reference axis. The equipment 40 functions as, or can be provided with, a fourth reflector.

The equipment 40 can be any piece of interest, including but not limited to: a wafer table, a lens or mirror, a mask table or a mask, or another piece of equipment in the optical section of the lithographic apparatus LA.

A practical embodiment of the first interferometer and the second interferometer suitable for method and system of the present disclosure is provided in, for instance, US2021072088.

Respective first output signal 34 and second output signal 44 of the first and second interferometer respectively can be provided to a phase measurement device 50, also referred to as phase measurement board (PMB). The PMB provides an output 52. The output 52 may include a first phase difference 54 of the two reflections in the first interferometer 20.

The output 52 of the PMB can also include a second phase difference of the two reflections in the second interferometer 22, to allow position measurement of the device 40. For a description in detail, reference is made to, for instance, literature referenced herein above.

The first phase difference 54 can be referred to as the wavelength tracker phase or ØWLT. The wavelength tracker phase 54 can be provided to a datalogger 56. The datalogger may log, i.e. make a record of, the measured wavelength tracker phase.

The wavelength tracker phase 54 can also be provided to the addition device 7, to function as a feedback signal to correct the setpoint of the laser source 2. The functioning hereof will be described below.

The datalogger 56 may also be provided with an absorption cell output 58, i.e. an output of the absorption cell 10. The output of the absorption cell typically includes an intensity spectrum I as a function of the frequency or wavelength of the laser beam 4.

The wavelength tracker phase 54 and the absorption cell output 58 may be provided to a processor 60. The processor 60 may be any type of suitable data processor, such as a computer or computer module. Another input 62 to the processor 60 may include a reference transmission spectrum of the absorption cell 10. The input 62 may include a pre-calibrated transmission spectrum I of the absorption cell 10 as a function of wavelength λ of the laser 2. The pre-calibrated spectrum is typically provided by a producer or manufacturer of the respective absorption cell. As the pre-calibrated spectrum has typically been created in a controlled laboratory environment with state of the art accuracy, said wavelength λ herein may also be referred to as actual wavelength, absolute wavelength, or reference wavelength.

An output 66 of the processor 50 can be used for a step 68 in the method of the present disclosure.

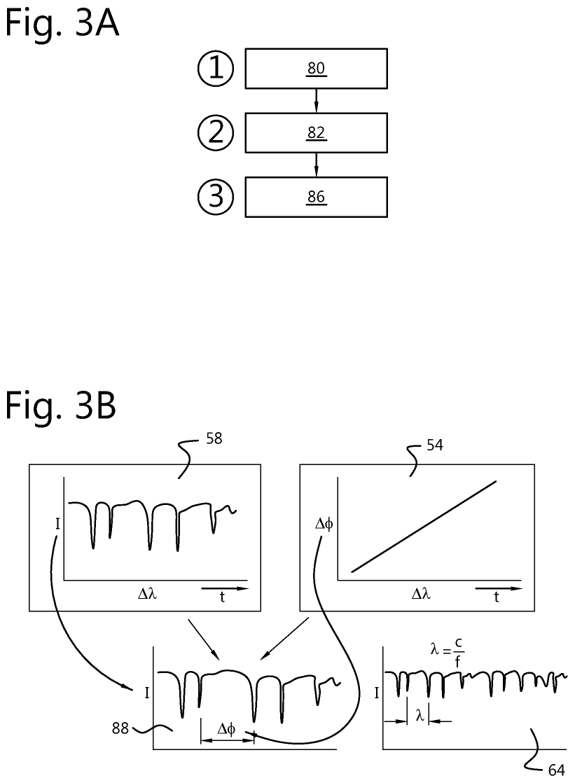

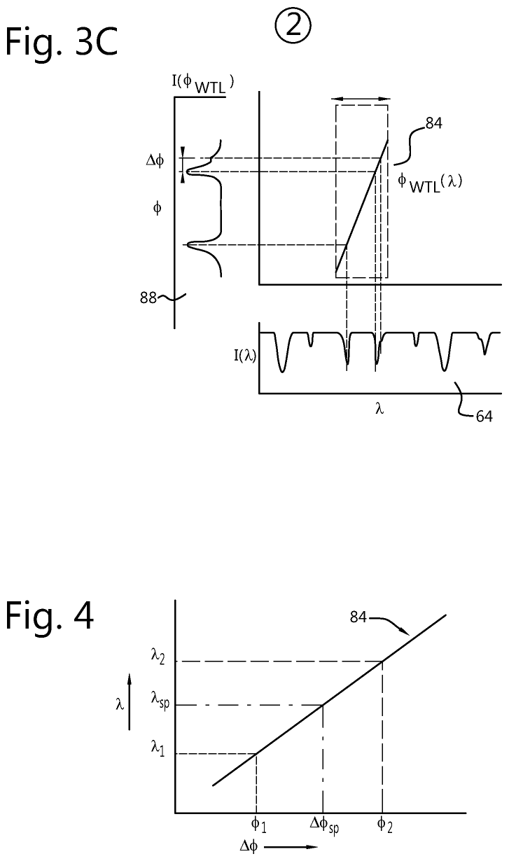

The method of the disclosure will be described with reference to FIGS. 3A, 3B, 3C and 4. Herein, certain general steps are labelled (1), (2), and (3). These generic indicators are also included in the schematic overview of the system in FIG. 2, to indicate where in the system these steps take effect.

Generally referring to FIG. 3A, a method of the disclosure includes at least steps labelled (1), (2), and (3). In a first step 80, the method measures the wavelength tracker phase difference 54 and the transmission spectrum 58 of the gas reference cell 14 while tuning the laser. Tuning the laser herein means, for instance, controlling the laser source 2 to sweep to wavelength of the laser beam 4 from the first wavelength λ₁ to the second wavelength λ₂. In a practical embodiment, the sweep may involve increasing and decreasing the wavelength repeatedly from the first wavelength λ₁ to the second wavelength λ₂ and vice versa.

In a second step 82, a correlation is made between the intensity spectrum 58 of the absorption cell, the wavelength tracker phase 54, and the pre-determined intensity spectrum 64, to find a function 84 of wavelength tracker phase as a function of absolute wavelength.

The first step 80 and the second step 82 may be referred to as tuning mode or calibration mode.

In a third step 86, which can be referred to as operating mode, a setpoint wavelength λₛₚ is selected. The wavelength of the laser source 2 is controlled as a function of the wavelength tracker phase 54 (φ_{WLT}). Herein, if the wavelength tracker phase 54 (φ_{WLT}) starts to deviate from a wavelength tracker phase setpoint (φₛₚ) corresponding to the setpoint wavelength λₛₚ as determined using the function 84 (see FIG. 4), the wavelength can be adjusted until the wavelength tracker phase has returned to the wavelength tracker phase setpoint (φₛₚ).

FIG. 3B generically indicates exemplary diagrams indicating the measured output 58 of the absorption cell 10 and the output 54 of the wavelength tracker. The first output 58 is an indication of intensity I as a function of time (expressed in, or related to, wavelength difference Δλ with respect to a starting point, such as the first wavelength). The second output 54 is the phase difference Δφ_{WLT} of the two light beams in the wavelength tracker 20 as a function of time (expressed in, or related to, the wavelength difference Δλ with respect to the starting point of the sweep). The two outputs 54 and 58 can be combined to arrive at a function 88 indicating absorption cell intensity I as a function of the phase difference Δφ_{WLT} of the wavelength tracker 20.

If we do not assume a linear wavelength trajectory, then the traced measurements gas transmission 58 and WLT phase 54 are all traced as function of time. By combining 58 and 54 we can plot 58 as function of 54 which can be correlated to 64 to find the linear dependency of WLT phase and absolute wavelength.

The function 88 can be fitted to the pre-calibrated diagram 64 of absorption cell intensity I as a function of absolute wavelength. The fit results in the relation or function 84 of the phase difference Δφ_{WLT} of the wavelength tracker 20 and absolute wavelength λ, as exemplified in FIG. 4.

Suitable fitting methods may include, but are not limited to, methods described in “A novel laser intensity function and its fitting method”, Optics & Laser Technology, Volume 47, April 2013, Pages 183-188, Yuan Wen-quan et al.

FIG. 3C diagrammatically indicates an exemplary method of fitting the function 88 to the pre-calibrated diagram 64 of absorption cell intensity I as a function of absolute wavelength λ. Herein, peaks, valleys, and generally any recognizable part of the respective curves may be fitted onto each other using a fitting method of choice. The fit results in the relation 84 [Δφ_{WLT}(λ)] of the wavelength tracker phase difference Δφ_{WLT} and absolute wavelength λ.

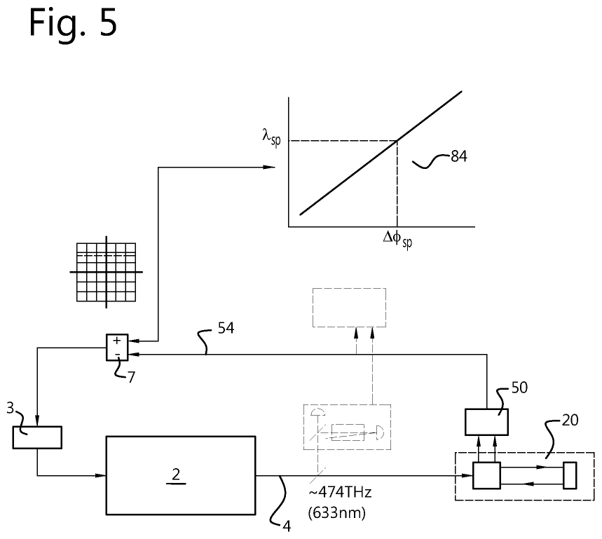

FIG. 5 indicates that parts of the laser device 1 active in an operational mode. Herein, the wavelength tracker interferometer 20 is continuously in operation, to allow continuous monitoring of deviation of the wavelength tracker phase difference Δφ_{WLT} from the wavelength tracker phase setpoint (φₛₚ). Continuous operation of the wavelength tracker 20 is both an advantage and a prerequisite. The advantage is that any deviation from the wavelength tracker phase setpoint (φₛₚ) can immediately lead to appropriate correction of the related wavelength A. Thus, the laser source can be controlled to immediately and accurately return to the setpoint wavelength Asp. It is also a prerequisite, as the wavelength tracker phase difference Δφ_{WLT} inherently moves in cycles of 360 degrees, so measurements of deviation from the setpoint must be continuous to be meaningful. As long as the wavelength tracker is active however, new sweeps of the trajectory generator 5 are obviated and the system can, and in practice does, continue to operate over relatively long periods of time uninterrupted. Long periods herein may indicate periods of multiple days, weeks, or even months.

Please note that the system of FIG. 5 may also include, and in practice often will include, a second interferometer 22 for measuring movement and location of selected equipment 40. In the operational mode, the second interferometer 22 will typically also be active. The setup and functioning thereof is similar to the embodiment depicted in and as described with reference to FIG. 2.

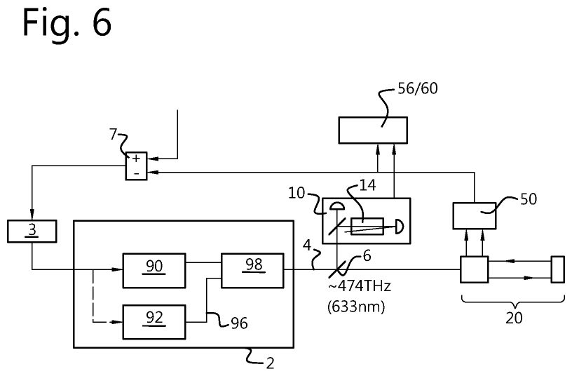

FIG. 6 shows an embodiment wherein the tunable laser source 2 includes at least two lasers 90, 92. One or both of the first laser 90 and the second laser 92 may be tunable, i.e. may have a variable frequency or wavelength. Respective first laser beam 94 and second laser beam 96 output from the lasers 90, 92 are combined. For instance, both beams can be directed to a summing device 98. The device 98 may be a crystal. A suitable crystal may include Periodically Poled Lithium Niobate (PPLN).

For more detail and practical examples of the summing crystal 98, reference is made to, for instance, “Double-pass high-efficiency sum-frequency generation of a broadband orange laser in a single MgO:PPLN crystal”, Optical Materials Express Vol. 9, Issue 2, pp. 837-844 (2019) [https://doi.org/10.1364/OME.9.000837], by Dismas K. Choge et al.

The first laser 90 may be a source for outputting light at about 282 THz. The second laser 92 may be a source for outputting light at about 192 THz. The summed output leading to light beam 4 may have a frequency in the order of 474 THz (wavelength in the order of 633 nm).

Herein below, information is provided with respect to practical embodiments of the method and system of the present disclosure, as well as additional advantages and methods of use.

The laser source includes a tunable laser, for instance a DFB laser, ELC laser, DBR laser, an FP laser (Fabry-Perot laser), a SFG (sum-frequency generation) laser, a SHG (harmonic generation) laser, or gas laser.

Depending on the type of laser, wavelength tuning can typically be achieved by adjusting temperature, current and/or control of a controllable filter (stretching a fiber brag or tilting a freespace grating (ECL), or a combination thereof.

If the laser is a sum-frequency laser (see FIG. 6 for an example), then the wavelength control may be obtained by either tuning one of the input lasers or by tuning both input lasers simultaneously.

The method first calibrates the phase of a mechanically ultrastable interferometer axis (wavelength tracker 20) against the spectral absorption spectrum of a molecular absorption gas cell 10. In a practical embodiment, the gas reference cell 14 of the absorption cell contains iodine vapour. Once calibrated, the setpoint for the phase of the wavelength tracker can be freely selected to match the phase that corresponds to a desired laser frequency or wavelength.

By locking to the phase of the wavelength tracker, the method and system effectively stabilize the laser wavelength instead of the laser frequency. The control loop that keeps a constant phase in the wavelength tracker signal prevents cyclic errors to present themselves.

Laser light is used as input for the highly stable phase interferometer axis (the axes of interferometer 20) with preferably a long OPD. The same laser light is used to measure the transmittance of the molecular absorption cell 10. The laser can receive a control input signal to tune the laser frequency.

Step1: Introduce a frequency sweep of the laser source (open loop or closed loop). Measure the phase of the interferometer axis and the transmission of the absorption cell. During this measurement the refractive index of the medium in the wavelength tracker is assumed to remain constant.

Step 2: Identify absorption dip locations and fit (a part of) the measured transmission curve to the pre-calibrated curve 64. Now the absolute laser frequency is known as a function of the phase of the stable reference 20.

Step 3: Define a new phase setpoint for the stable reference axis to tune the laser to a desired laser frequency or wavelength. From this point on the laser frequency control loop will actually stabilize the laser wavelength inside the ultrastable wavelength tracker cavity (the internals of interferometer 20).

The phase interferometer 20 may for example be a homodyne or a heterodyne interferometer.

The molecular absorption cell 10 may be used in single pass, multipass configuration, or be positioned inside an optical resonator to increase the circulating power. A signal power reference detector will typically be used to compensate for laser power variations when determining the reference cell transmission curve.

By determining the laser frequency or wavelength as a function of the phase of an ultrastable reference axis and then locking the laser to the phase of this ultrastable interferometer axis, there is no wavelength modulation required to keep the laser locked.

Locking the laser wavelength to the phase of a ultrastable cavity allows the laser wavelength to be locked to an arbitrary wavelength value and not just to a frequency that coincides with the spectral line of a molecular absorption cell.

Ultrastable herein may relate to, for instance, a system using an optical cavity with 5×10⁻¹⁷ thermal noise limit. Such a system may use a 30-cm-long ULE cavity, fused-silica mirror substrates, and crystalline mirror coatings. As another example, an ultrastable laser system may include optical cavities with reduced thermal noise. Such system may have an instability in the order of 5×10⁻¹⁶@1s. The latter is very low, allowing to refer to the respective cavity as being ultrastable.

Compared to the conventional systems discussed in the introduction:

US20020043616A1 uses an etalon which lacks a phase measurement. As such, a linear curve for calibration would not and cannot be determined.

US20200182702A1 describes a tunable laser system in which the laser is tuned over a range of frequencies and output to an interferometer having a plurality of outputs. A wavelength reference, such as a gas cell, can be used in combination with at least two interferometer outputs to produce an absolute measurement of the tunable laser wavelength. Although the document discusses using a “continuous phase signal” from the interferometer as a measurement of the laser wavelength it lacks a disclosure of using one stable reference for this. As such, there is no prior ‘locking’ of the wavelength. Instead, the system does a repeated calibration continuously. To the contrary, the system and method of the present disclosure calibrate once and then use the laser without having to carry out subsequent wavelength tuning.

The method and system obviate cyclic errors. Locking the laser frequency or wavelength to the phase of the wavelength tracker eliminates the impact of cyclic errors due to refractive index changes.

By locking the laser frequency or laser wavelength to the phase of the wavelength tracker, the laser wavelength becomes insensitive to refractive index variations of the surrounding medium.

The wavelength tracker traditionally is intended to measure laser frequency and refractive index noise. This noise is supposed to be subtracted from any interferometer axis that shares the same source and medium with a proper gain factor. The gain factor is equal to the OPD ratio between the interferometer axis and the wavelength tracker axis. By stabilizing the laser wavelength in the wavelength tracker instead of the laser frequency in the source, wavelength compensation is inherent and no longer has to be applied in software. This means that the compensation no longer requires information about the OPD ratio is available.

The method of the present disclosure enables to track the actual wavelength of the laser output. In other words, the actual wavelength of the laser output—which may deviate albeit ever so slightly from the set wavelength—is adjusted rather than the wavelength as set. Herein, the phase difference in the interferometer can be measured continuously, and provides a continuous signal. The latter enables to correct and adjust deviations from a setpoint wavelength immediately and accurately. Thus, the method and systems including the method enable more accurate adjustment and control of laser wavelength.

In a practical embodiment, the laser source 2 may comprise one or more Helium-Neon (HeNe) lasers. The lasers may have an operable wavelength of around 633 nm and output power on the order of 1 mW. Such lasers are suitable for displacement interferometry applications in for instance lithography machines (including DUV and EUV), mask inspection and mask writing equipment. Please note that these values are exemplary only. Other wavelengths for the interferometer systems are conceivable within the scope of the disclosure.

For long distance displacement interferometry a stabilized laser source is typically used, with a coherence length that is larger than the measured optical pathlength difference. Zeeman-stabilized and two-mode frequency-stabilized HeNe lasers have shown instabilities on the order of about 100 kHz and a long term stability of better than a few MHz. HeNe lasers with internal (or external) iodine reference cells stabilized to Doppler-free molecular hyperfine lines of iodine may achieve an instability down to sub-pm levels per meter over periods of hours.

HeNe laser frequencies are inherently sensitive to vibrations from the surroundings, for example from an electronics rack, which can excite the eigenmodes of the laser tube. For fiber-coupled interferometers, pointing drift of the HeNe laser may introduce coupling losses over time requiring regular checks and coupling optimization. To compensate for wavelength stability noise, which may originate from the laser source or from refractive index noise, the HeNe laser can be operated with a dedicated wavelength tracker in accordance with the present disclosure.

Other suitable tunable laser sources include various types of frequency doubled lasers which enable outputs on the order of multiple watts with high beam quality. For instance a beam having a wavelength of 660 nm can be generated with frequency doubled Nd:YAG lasers, 656.5 nm with ND:YLF, or 671 nm with Nd:YVO₄ or Nd:GdVO₄.

All of the lasers indicated above will require frequency or wavelength stabilization in order to be useful for long distance metrology applications. Herein, the disclosure suggest to replace known and commercially available laser stabilization methods with a method as described herein above.

Fast laser frequency or wavelength control may, depending on the laser type, typically be achieved by one or more of: Piezo control (cavity length/grating tilt); Current control; and Thermal control (slow).

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Features of respective embodiments may for instance be combined. Other aspects of the invention are set-out as in the following numbered clauses.
1. A method to stabilize a wavelength of a tunable laser device, comprising the steps of: simultaneously providing a laser beam from a tunable laser source to a first interferometer having a mechanically stable reference axis and to a gas absorption cell;
scanning a wavelength range with the laser beam from a first wavelength to a second wavelength;
determining a transmission spectrum of the gas absorption cell as a function of the wavelength difference with respect to the first wavelength;
using the first interferometer to determine a phase change as a function of the wavelength difference with respect to the first wavelength;
determining a transmission spectrum as a function of the phase change using the transmission spectrum of the gas absorption cell and the phase change as a function of the wavelength difference;
correlating the determined transmission spectrum as a function of phase change to a pre-calibrated transmission spectrum of the tunable laser device to provide an absolute laser wavelength as a function of the phase change;
defining a phase setpoint corresponding to a wavelength setpoint; and
using the phase setpoint to tune the tunable laser device to the wavelength setpoint.
2. The method of clause 1, including the step of using the laser beam set at the setpoint wavelength to measure displacement of a device in a lithographic apparatus.
3. The method of clause 2, wherein the step of using the laser beam to measure displacement includes providing the laser beam to a second interferometer.
4. The method of clause 2 or 3, the device comprising a wafer table, a wafer, a mask, a mask table, or any other piece of equipment in the optical stage of the lithographic apparatus.
5. The method of clause 1, the steps of correlating the determined transmission spectrum as a function of phase change to the pre-calibrated transmission spectrum of the tunable laser device comprising: fitting the determined transmission spectrum to the pre-calibrated transmission spectrum using a fitting algorithm.
6. The method of any one of the previous clauses, the step of using the phase setpoint to tune the tunable laser device to the setpoint wavelength comprising continuously using the first interferometer to determine a phase change with respect to the phase setpoint.
7. A tunable laser device, comprising:
a tunable laser source for providing a laser beam;
a first interferometer having a mechanically stable reference axis adapted to receive the laser beam;
a gas absorption cell adapted to receive the laser beam simultaneously with the interferometer;
a processor adapted for:
scanning a wavelength range with the laser beam from a first wavelength to a second wavelength;
determining a transmission spectrum of the gas absorption cell as a function of time;
using the first interferometer to determine a phase change as a function of time;
determining a transmission spectrum as a function of the phase change using the transmission spectrum of the gas absorption cell and the phase change as a function of time;
correlating the determined transmission spectrum as a function of phase change to a pre-calibrated transmission spectrum of the tunable laser device to provide an absolute laser wavelength as a function of the phase change;
defining a phase setpoint corresponding to a wavelength setpoint; and using the phase setpoint to tune the tunable laser device to the wavelength setpoint.
8. The tunable laser device of clause 7, wherein determining a transmission spectrum of the gas absorption cell as a function of time includes correlating time to the wavelength difference with respect to the first wavelength.
9. The tunable laser device of clause 7 or 8, wherein the using the first interferometer to determine a phase change as a function of time includes correlating time to the wavelength difference with respect to the first wavelength.
10. The tunable laser device of clause 7, the laser device being adapted to use the laser beam set at the wavelength setpoint to measure displacement of a device in a lithographic apparatus.
11. The tunable laser device of clause 10, comprising a second interferometer adapted to receive the laser beam to measure displacement.
12. The tunable laser device of clause 10 or 11, the device in the lithographic apparatus comprising a wafer table, a wafer, a mask, a mask table, or any other piece of equipment in the optical stage of the lithographic apparatus.
13. The tunable laser device of one of clauses 7 to 12, the processor being adapted to correlate the determined transmission spectrum to the pre-calibrated transmission by fitting the determined transmission spectrum to the pre-calibrated transmission spectrum using a fitting algorithm.
14. The tunable laser device of any one of clauses 7 to 13, the tunable laser device being adapted to have an operating mode, wherein the first interferometer is adapted to continuously determine a phase change with respect to the phase setpoint.
15. A position measurement system, comprising a tunable laser device according to clause 7 and/or adapted to implement the method of clause 1.
16. A lithographic apparatus, comprising at least one position measurement system according to clause 15.

1-16. (canceled)

17. A method to stabilize a wavelength of a tunable laser device comprising:
simultaneously providing a laser beam from a tunable laser source to a first interferometer having a mechanically stable reference axis and to a gas absorption cell;
scanning a wavelength range with the laser beam from a first wavelength to a second wavelength;
determining a transmission spectrum of the gas absorption cell as a function of the wavelength difference with respect to the first wavelength;
using the first interferometer to determine a phase change as a function of the wavelength difference with respect to the first wavelength;
determining a transmission spectrum as a function of the phase change using the transmission spectrum of the gas absorption cell and the phase change as a function of the wavelength difference;
correlating the determined transmission spectrum as a function of phase change to a pre-calibrated transmission spectrum of the tunable laser device to provide an absolute laser wavelength as a function of the phase change;
defining a phase setpoint corresponding to a wavelength setpoint; and
using the phase setpoint to tune the tunable laser device to the wavelength setpoint.

18. The method of claim 17, further comprising using the laser beam set at the setpoint wavelength to measure displacement of a device in a lithographic apparatus.

19. The method of claim 18, wherein the using the laser beam to measure displacement comprises providing the laser beam to a second interferometer.

20. The method of claim 18, further comprising using a wafer table, a wafer, a mask, a mask table, or any other piece of equipment as the tunable laser device in an optical stage of the lithographic apparatus.

21. The method of claim 17, wherein the correlating the determined transmission spectrum as a function of phase change to the pre-calibrated transmission spectrum of the tunable laser device comprises:
fitting the determined transmission spectrum to the pre-calibrated transmission spectrum using a fitting algorithm.

22. The method of claim 17, wherein the using the phase setpoint to tune the tunable laser device to the setpoint wavelength comprises continuously using the first interferometer to determine a phase change with respect to the phase setpoint.

22. A tunable laser device, comprising:
a tunable laser source configured to provide a laser beam;
a first interferometer comprising a mechanically stable reference axis adapted to receive the laser beam;
a gas absorption cell adapted to receive the laser beam simultaneously with the interferometer; and
a processor adapted for:
scanning a wavelength range with the laser beam from a first wavelength to a second wavelength;
determining a transmission spectrum of the gas absorption cell as a function of time;
using the first interferometer to determine a phase change as a function of time;
determining a transmission spectrum as a function of the phase change using the transmission spectrum of the gas absorption cell and the phase change as a function of time;
correlating the determined transmission spectrum as a function of phase change to a pre-calibrated transmission spectrum of the tunable laser device to provide an absolute laser wavelength as a function of the phase change;
defining a phase setpoint corresponding to a wavelength setpoint; and
using the phase setpoint to tune the tunable laser device to the wavelength setpoint.

23. The tunable laser device of claim 22, wherein the determining a transmission spectrum of the gas absorption cell as a function of time comprises correlating time to the wavelength difference with respect to the first wavelength.

24. The tunable laser device of claim 22, wherein the using the first interferometer to determine a phase change as a function of time comprises correlating time to the wavelength difference with respect to the first wavelength.

25. The tunable laser device of claim 22, wherein the tunable laser device is adapted to use the laser beam set at the wavelength setpoint to measure displacement of a device in a lithographic apparatus.

26. The tunable laser device of claim 25, further comprising a second interferometer adapted to receive the laser beam to measure displacement.

27. The tunable laser device of claim 25, wherein the tunable laser device in the lithographic apparatus comprises a wafer table, a wafer, a mask, a mask table, or any other piece of equipment in an optical stage of the lithographic apparatus.

28. The tunable laser device of claim 22, wherein the processor is further adapted to correlate the determined transmission spectrum to the pre-calibrated transmission by fitting the determined transmission spectrum to the pre-calibrated transmission spectrum using a fitting algorithm.

29. The tunable laser device of claim 22, wherein:
the tunable laser device is adapted to have an operating mode, and
the first interferometer is adapted to continuously determine a phase change with respect to the phase setpoint.

30. A position measurement system, comprising:
the tunable laser device according to claim 22.

31. A position measurement system, comprising:
adapted to implement the method of claim 17.

32. A lithographic apparatus, comprising:
at least one of the position measurement system according to claim 30.

33. A lithographic apparatus, comprising:
at least one of the position measurement system according to claim 31.
